(19) United States
(12) Patent Application Publication
(10) Pub. No.: US 2017/0317207 A1
(43) Pub. Date: Nov. 2, 2017

(54) TRENCH MOSFET STRUCTURE AND LAYOUT WITH SEPARATED SHIELDED GATE

(71) Applicant: Force Mos Technology Co., Ltd., New Taipei City (TW)

(72) Inventor: Fu-Yuan HSIEH, New Taipei City (TW)

(21) Appl. No.: 15/141,907

(22) Filed: Apr. 29, 2016

(51) Int. Cl. H01L 29/78; H01L 21/265; H01L 29/423; H01L 29/417; H01L 29/40; H01L 29/36; H01L 29/167; H01L 29/10; H01L 29/08; H01L 29/06; H01L 21/3213; H01L 21/321; H01L 21/3205; H01L 21/308; H01L 21/266; H01L 29/66

(52) U.S. Cl. CPC H01L 29/7813; H01L 29/7811; H01L 21/26513; H01L 29/42376; H01L 29/4236; H01L 29/41766; H01L 29/407; H01L 29/36; H01L 29/167; H01L 29/1095; H01L 29/0865; H01L 29/0696; H01L 29/0661; H01L 21/32137; H01L 21/3212; H01L 21/32055; H01L 21/3086; H01L 21/266; H01L 29/66734

(57) ABSTRACT

A trench MOSFET with closed cell layout having shielded gate is disclosed, wherein closed gate trenches surrounding a deep trench in each unit cell and the shielded gate disposed in the deep trench. Trenched source-body contacts are formed between the closed gate trenches and the deep trench. The deep trench has square, rectangular, circle or hexagon shape.

### FIELD OF THE INVENTION

This invention relates generally to the cell structure, device configuration and fabrication process of semiconductor power device. More particularly, this invention relates to a novel and improved cell structure, device configuration and improved fabrication process of a trench MOSFET (Metal Oxide Semiconductor Field Effect Transistor).

### BACKGROUND OF THE INVENTION

Please refer to FIG. 1 for an N-channel trench MOSFET 20 disclosed in a prior art of U.S. Pat. No. 7,557,409 wherein trenches 204A and 204B respectively comprise: gate electrodes 208A and 208B in the upper portion; and buried source electrodes 212A and 212B in the lower portion, wherein said source electrodes 212A and 212B are connected to source metal 224. FIG. 2 illustrates that the prior art comprises a plurality of annular trenches separated by annular mesas in top view, in which the cross-section 2-2 could be represented by FIG. 1. FIG. 1C shows the geometric pattern of metal layer of the prior art, wherein a gate metal layer 225 extends outward from a central region in a plurality of gate metal legs (2250A-2250D) separated by source metal regions 2240A-2240D.

Since the gate electrodes (208A, for example) and the buried source electrodes (212A, for example) are located in the same trench (204), the trench 204 is required to be wider than 1.2 um for medium voltage device due to thicker filled oxide 216A in the lower portion of the trench, meanwhile, the trench MOSFET 20 requires a single thick doped poly deposition (>0.8 um) or multiple doped poly deposition for gate electrode formation, which increases fabricating cost.

At the same time, the gate oxide 218A is required to be grown at a higher temperature (>1100 C) to avoid the gate oxide thinning issue (at interface between the gate oxide 218A and the thick filled oxide 216A), which will cause high leakage current issue between the gate electrode 208A and the buried source electrode 212A.

At the same time, the geometric pattern of the gate metal layer 225 extending from a gate metal pad located in central portion of the device causes design difficulty because the gate metal pad is usually located in one of four device corners.

Therefore, there is still a need in the art of the semiconductor power device, particularly for trench MOSFET design and fabrication, to provide a novel cell structure, device configuration and fabrication process that would resolve these difficulties.

### SUMMARY OF THE INVENTION

The present invention provides a trench MOSFET with separated shielded gate, which comprises at least one gate trench surrounding a deep trench wherein a shielded gate being formed inside the deep trench, and further comprises a trenched source-body contact disposed between the gate trench and the deep trench.

In one aspect, the present invention features a trench MOSFET having shielded gate, comprising: at least one gate trench surrounding a deep trench as a closed cell shape, wherein the deep trench comprises a shielded gate formed inside; and a trenched source-body contact disposed between one gate trench and an adjacent deep trench.

In another aspect, the present invention further comprises: a substrate of a first conductivity type; an epitaxial layer of the first conductivity type onto the substrate, wherein the epitaxial layer has a lower doping concentration than the substrate; the deep trench having a greater trench depth than the gate trench; the shielded gate being formed within the deep trench and surrounded with a dielectric material; a mesa area between a pair of adjacent deep trenches; a body region of a second conductivity type extending in the mesa area; a source region of the first conductivity type above the body region, locating between sidewall of each gate trench and adjacent trenched source-body contact; the gate trench filled with gate electrode padded by a gate oxide layer, starting from top surface of the epitaxial layer and down penetrating through the source region and extending into the epitaxial layer in the mesa area, wherein the gate oxide layer has a thickness thinner than the dielectric material ; and a source metal connected with the shielded gate through a shielded gate contact and connected with the source region through the trenched source-body contact.

In another aspect, the present invention further comprises a trench bottom ion implantation region of the first conductivity type and surrounding at least bottom of each gate trench under the body region.

In another aspect, in some preferred embodiment according to the present invention, the deep trench is formed within the epitaxial layer, and has a trench bottom above a common interface between the epitaxial layer and the substrate. In some other preferred embodiment according to the present invention, the deep trench is extending into the substrate, and has a trench bottom under a common interface between the epitaxial layer and the substrate.

In another aspect, the present invention features multiple gate trenches in the mesa area between a pair of deep trenches.

In another aspect, in some preferred embodiment according to the present invention, the gate trench has a square shape. In some other preferred embodiment, the gate trench has a rectangular shape and arranged in single orientation. In some other preferred embodiment, the gate trench has a rectangular shape and arranged in multiple orientation. In some other preferred embodiment, the gate trench has a circle shape. In some other preferred embodiment, the gate trench has a hexagon shape.

In another aspect, the present invention further comprises a body contact region of the second conductivity type in the body region and surrounding at least bottom of each trenched source-body contact, wherein the body contact region has a higher doping concentration than the body region.

In another aspect, the present invention further comprises a termination area which comprises at least a deep trench ring surrounding the active area, wherein each deep trench ring is filled with the shielded gate and connected with the source metal. In some preferred embodiment, the deep trench ring has trench depth and trench width same as the deep trench in the active area. In some other preferred embodiment, the deep trench ring has greater trench depth and greater trench width than the deep trench in the active area.

In another aspect, the present invention further comprises a gate metal runner extending from a gate metal pad, crossing over the termination area and connecting to the gate electrode. In some preferred embodiment, the deep trench ring surrounds not only the active area, but also portion of the gate metal pad.

The invention also features a method for manufacturing a trench MOSFET comprising the steps of: (a). growing an epitaxial layer of a first conductivity type upon a substrate of the first conductivity type, wherein the epitaxial layer having a lower doping concentration than the substrate; (b). forming a deep trench mask such as an oxide onto a top surface of the epitaxial layer for definition of a plurality of deep trenches; (c). forming the gate trenches, and a mesa between two adjacent deep trenches in the epitaxial layer by etching through open regions in the deep trench mask; (d). removing the hard mask; (e). forming a dielectric material along inner surfaces of the gate trenches by thermal oxide growth or oxide deposition; (f). depositing a first doped poly-silicon layer filling the deep trenches to serve as shielded gate; (g). etching back the first doped poly-silicon and the padded oxide layer from unnecessary portion; (h). etching a gate trench in the mesa between two adjacent deep trenches by applying a trench mask; (i). carrying out ion implantation of the first conductivity type to form trench bottom ion implantation area surrounding at least bottom of the gate trench; (j). forming a thin oxide layer to serve as a gate oxide layer covering a top surface of the epitaxial layer, along inner surface of the gate trench; (k). depositing a second doped poly-silicon layer filling the gate trench to serve as a gate electrode; (l). etching back the second doped poly-silicon layer by CMP (Chemical Mechanical Polishing) or plasma etch; (m). carrying out a body implantation of the second conductivity type dopant and a step of body diffusion to form body regions; (n). applying a source mask onto the top surface of the epitaxial layer, and carrying out a source implantation of the first conductivity type dopant and a source diffusion to form source regions; (o). forming a contact insulating interlayer covering top surface of the epitaxial layer; and (p). etching openings and filling contact metal plug in those openings to form shielded gate contacts and trenched source-body contacts.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a cross-sectional view of a trench MOSFET of a prior art.

FIG. 1B is a top view of the prior art.

FIG. 1C is shown the geometric pattern of gate metal and source metal of the prior art.

FIG. 2 is a cross-sectional view of a preferred embodiment according to the present invention.

FIG. 3 is a cross-sectional view of another preferred embodiment according to the present invention.

FIG. 4 is a cross-sectional view of another preferred embodiment according to the present invention.

FIG. 5 is a cross-sectional view of another preferred embodiment according to the present invention.

FIG. 6 is a cross-sectional view of another preferred embodiment according to the present invention.

FIG. 7 is a cross-sectional view of another preferred embodiment according to the present invention.

FIG. 8 is a top view of another preferred embodiment according to the present invention.

FIG. 9 is a top view of another preferred embodiment according to the present invention.

FIG. 10 is a top view of another preferred embodiment according to the present invention.

FIG. 11 is a top view of another preferred embodiment according to the present invention.

FIG. 12 is a top view of another preferred embodiment with termination area according to the present invention.

FIG. 13 is a top view of another preferred embodiment with termination area according to the present invention.

FIG. 14 is a top view of another preferred embodiment with termination area according to the present invention.

FIG. 15 is a preferred B1-B2 cross sectional view according to the present invention.

FIG. 16 is a preferred C1-C2 cross sectional view according to the present invention.

FIG. 17 is a preferred C1-C2 cross sectional view according to the present invention.

FIG. 18 is a preferred C1-C2 cross sectional view according to the present invention.

FIG. 19 is a top view of another preferred embodiment according to the present invention.

FIG. 20 is a top view of another preferred embodiment according to the present invention.

FIG. 21 is a top view of another preferred embodiment according to the present invention.

FIGS. 22A-22F are a serial of side cross-sectional views for showing the processing steps for fabricating the trench MOSFET of FIG. 5.

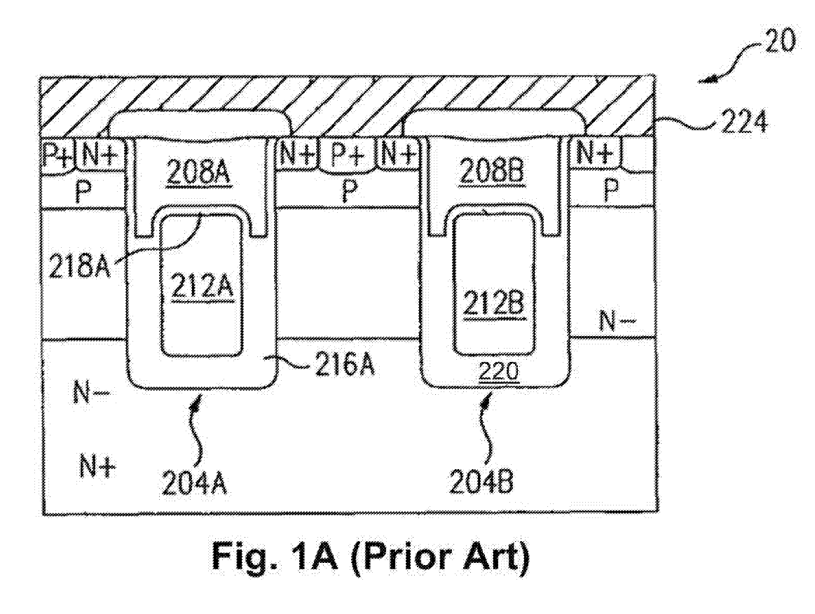

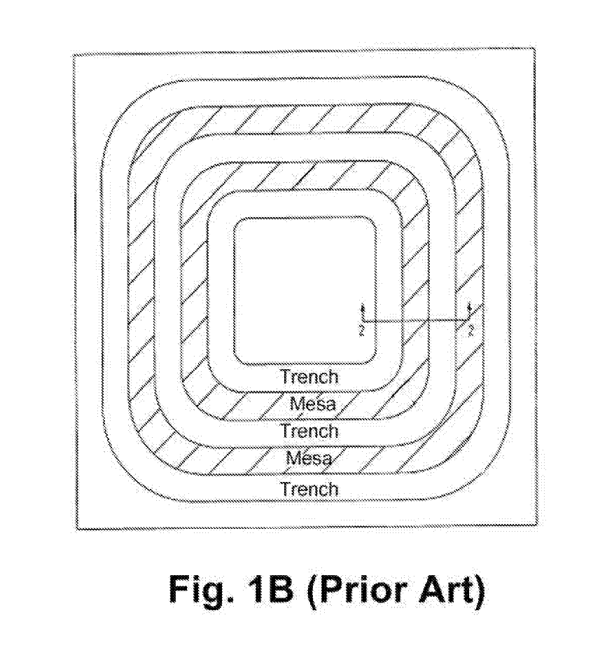

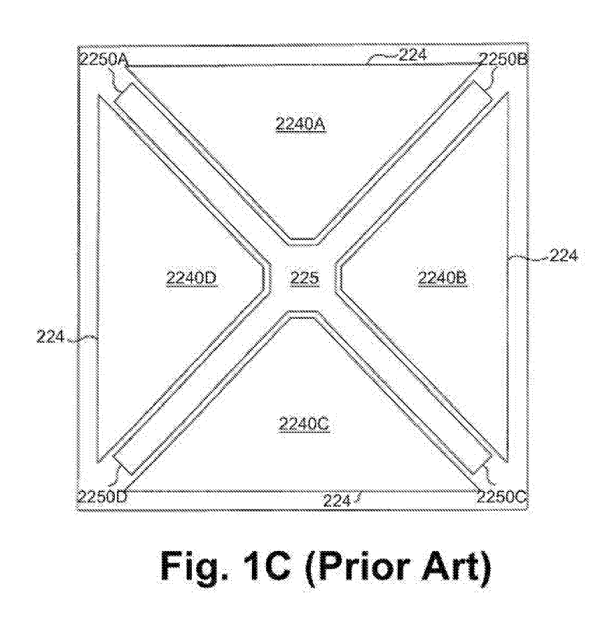

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be make without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

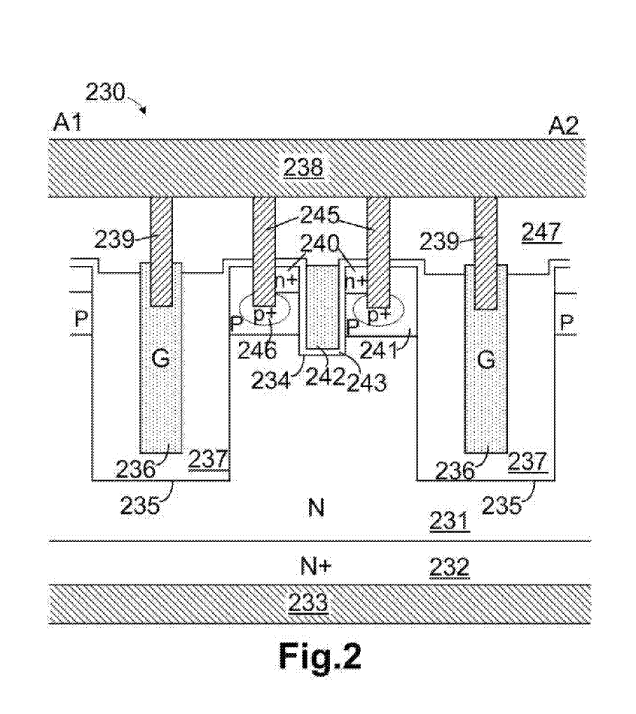

Please refer to FIG. 2 for a preferred embodiment of this invention wherein an N-channel trench MOSFET 230 is formed in an N-epitaxial layer 231 onto an N+ substrate 232 coated with a back metal 233 on rear side as a drain metal, wherein said back metal 233 can be implemented by using Ti/Ni/Ag. At least one gate trench 234 is formed surrounding a deep trench 235 as a closed shape in an active area, wherein there are multiple closed shape cells in the active area. Said deep trench 235 is starting from a top surface of said N-epitaxial layer 231 and extending downward into said N-epitaxial layer 231 in the active area, wherein trench bottom of said deep trench 235 is above a common interface between said N+ substrate 232 and said N-epitaxial layer 231. Said deep trench 235 is filled with a shielded gate 236 padded by a dielectric material 237, wherein said shielded gate 236 is connected to a source metal 238 through a shielded gate contact 239, which is penetrating through a contact insulation layer 247 and into said shielded gate 236. In a mesa area between a pair of said deep trenches 235, said at least one gate trench 234 is formed surrounded by an n+ source region 240 above a P body region 241, wherein said gate trench 234 is filled with a gate electrode 242 padded by a gate oxide layer 243, wherein said gate oxide layer 243 has a thickness thinner than said dielectric material 237. Between said gate trench 234 and an adjacent deep trench 235, a trenched source-body contact 245 filled with contact metal plug is located and penetrating through said contact insulation layer 247 and into said P body region 241, to connect said n+ source region 240 and said P body region 241 to said source metal 238, wherein said contact metal plug can be implemented by using tungsten plug. Said n+ source region 240 is only located between said trenched source-body contact 245 and sidewalls of said gate trench 234. Besides, a p+ body contact region 246 is formed surrounding bottom of each said trenched source-body contact 245 to reduce the contact resistance between said P body region 241 and said trenched source-body contact 245.

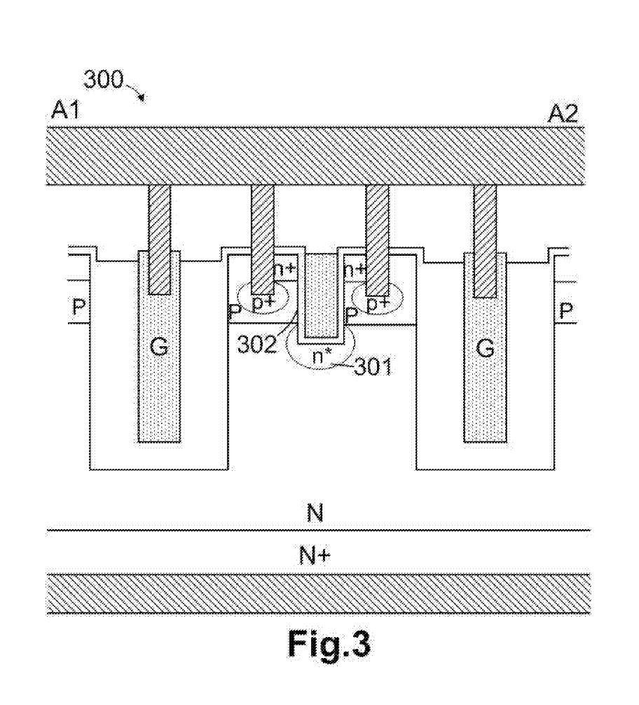

FIG. 3 is a cross-sectional view of another preferred embodiment according to the present invention for showing an N-channel trench MOSFET 300 which is similar to the trench MOSFET 230 in FIG. 2 except that, in FIG. 3, underneath the gate trench 308, an additional n* trench bottom ion implantation area 301 is formed surrounding at least bottom of the gate trench 308, in order to reduce gate charge as well as Rds.

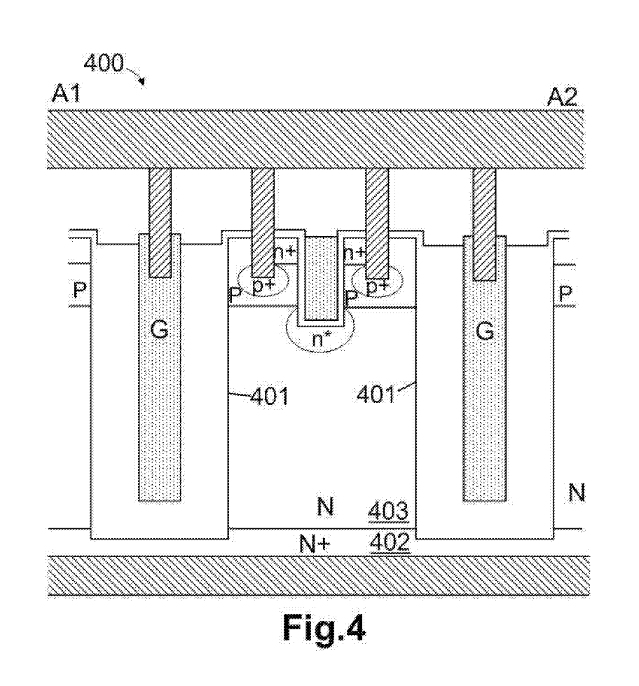

FIG. 4 is a cross-sectional view of another preferred embodiment according to the present invention for showing an N-channel trench MOSFET 400 which is similar to the trench MOSFET 300 in FIG. 3 except that, in FIG. 4, each said deep trench 401 is further extending into said N+ substrate 402, which means bottom of said each deep trench 401 is under an common interface between said N+ substrate 402 and said N epitaxial layer 403.

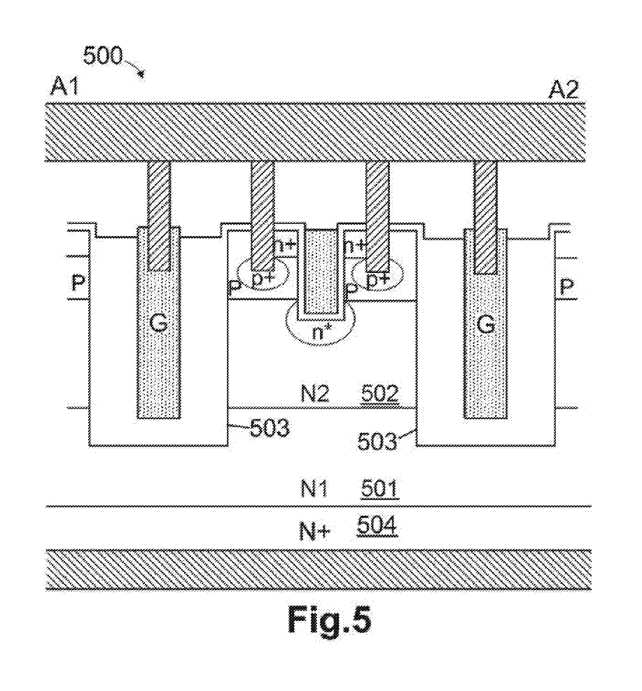

FIG. 5 is a cross-sectional view of another preferred embodiment according to the present invention for showing an N-channel trench MOSFET 500 which is similar to the trench MOSFET 300 in FIG. 3 except that, in FIG. 5, the N-channel trench MOSFET 500 further comprises a second epitaxial layer 502 of said N type formed in said mesa area and having a doping concentration N2 above a first epitaxial layer 501 having a doping concentration N1, wherein N2 is higher than N1. In this preferred embodiment, each said deep trench 503 is penetrating through said second epitaxial layer 502 and extending into said first epitaxial layer 501. In some other preferred embodiments, each said deep trench 503 has a bottom above common interface between said first epitaxial layer 501 and said N+ substrate 504.

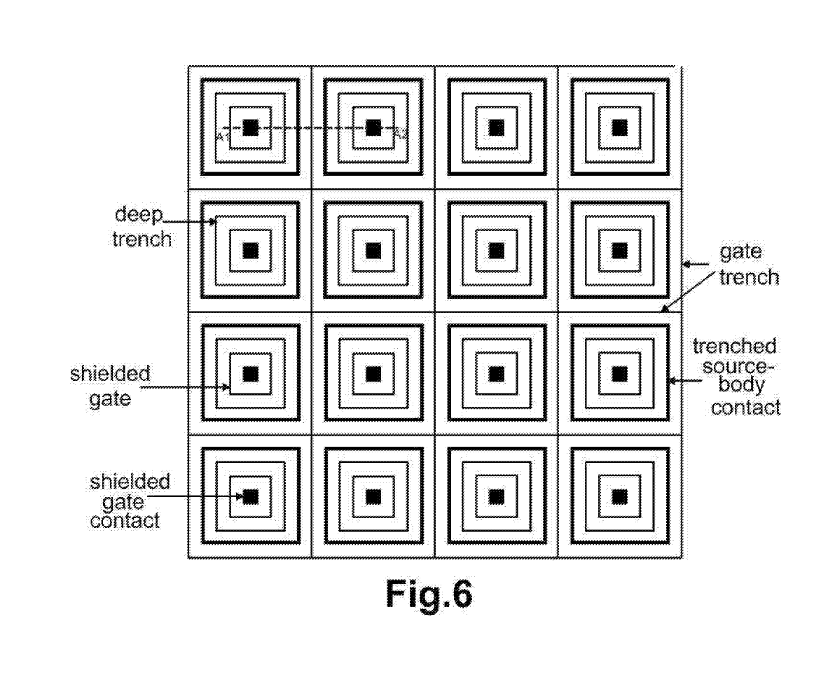

FIG. 6 shows a preferred top view according to the present invention with square closed cell layout. In which the preferred A1-A2 cross-sectional views could be represented by the embodiments shown in FIGS. 2˜5.

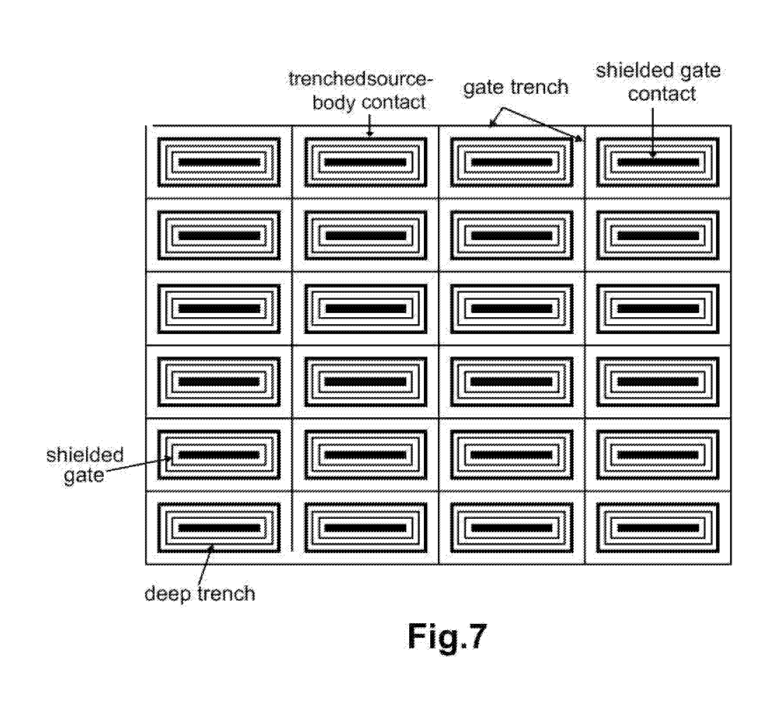

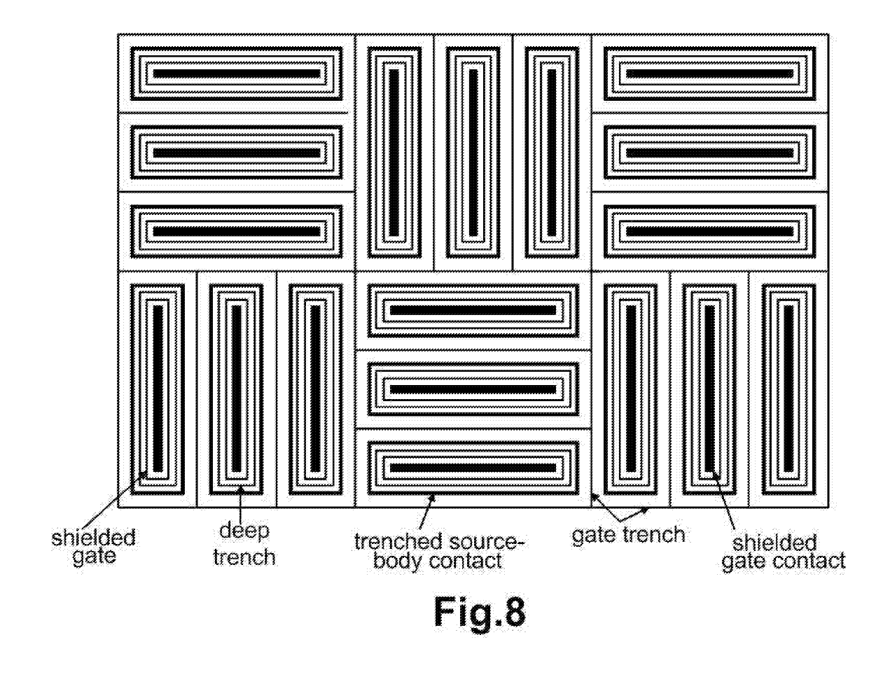

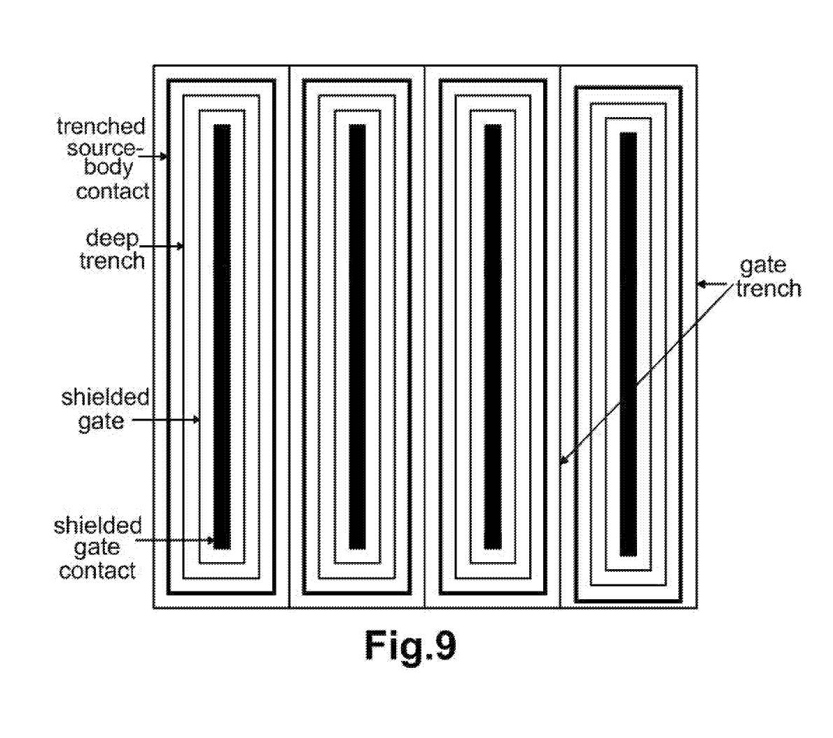

FIGS. 7-9 show another preferred top views according to the present invention. FIG. 7 shows a preferred top view with rectangular closed cell layer, in which all said rectangular closed cells are arranged in single orientation. FIG. 8 shows a preferred top view with rectangular closed cell layout, in which all said rectangular closed cells are arranged in multiple orientations. FIG. 9 shows a preferred top view with stripe cell layout.

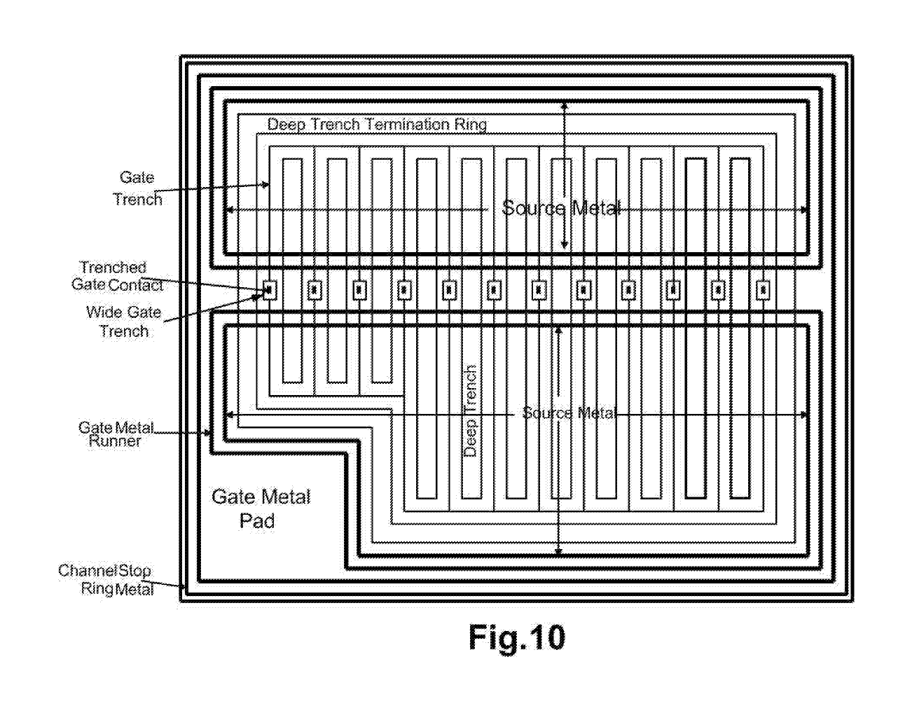

FIG. 10 shows another preferred top view according to the present invention with termination area which comprises at least one deep trench termination ring under source metal and surrounding an active area; gate metal runner surrounding outer of the deep trench termination ring; and channel stop ring metal surrounding outer of the gate metal runner. According to this embodiment, all the deep trenches in the active area have stripe shape, and each said gate electrode in the gate trenches is connected to said source metal through said trenched gate contact in a wide gate trench. And the gate metal pad is located in a corner of the device, which is more cost effective.

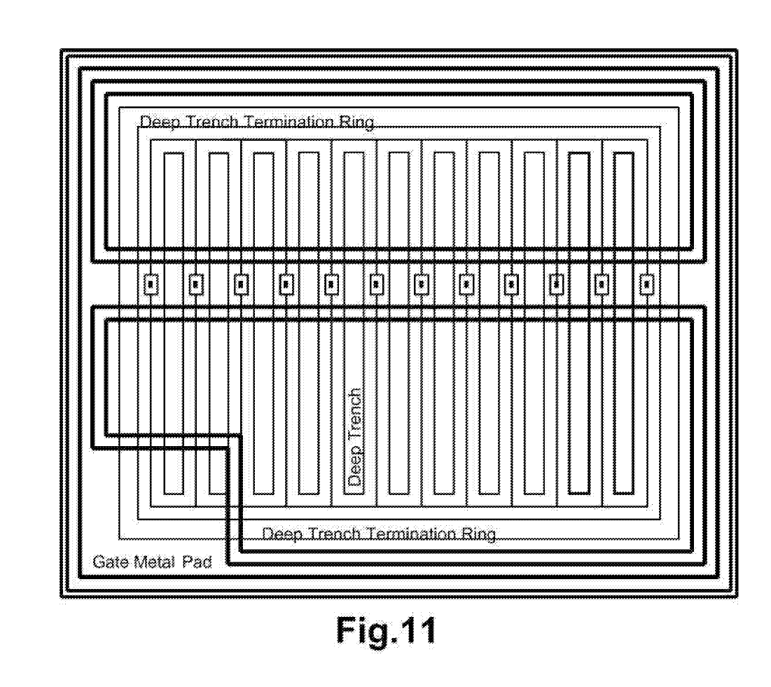

FIG. 11 shows another preferred top view according to the present invention with termination area which is similar to FIG. 10, except that, in FIG. 11, the deep trench termination ring surrounds not only the active area but also portion of the gate metal pad.

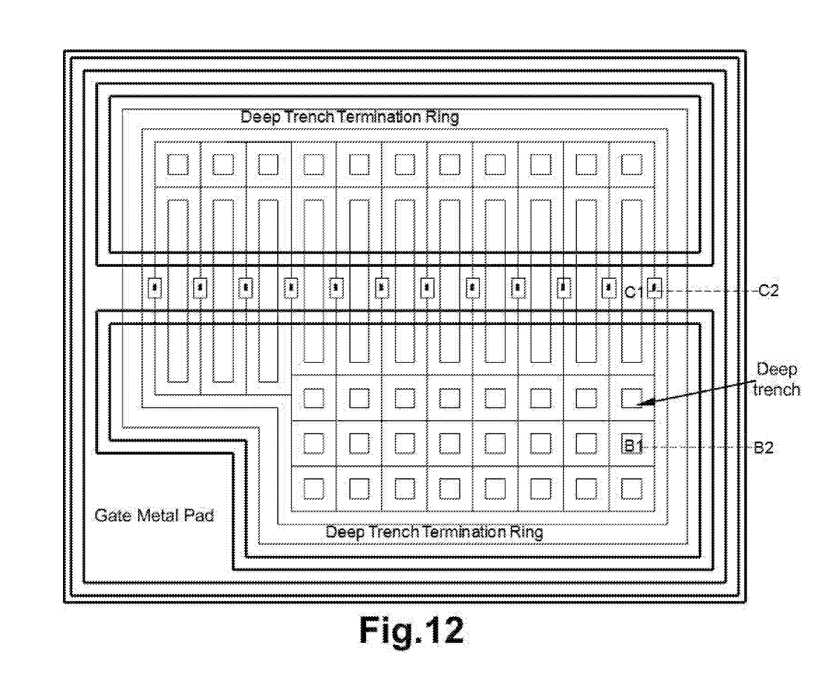

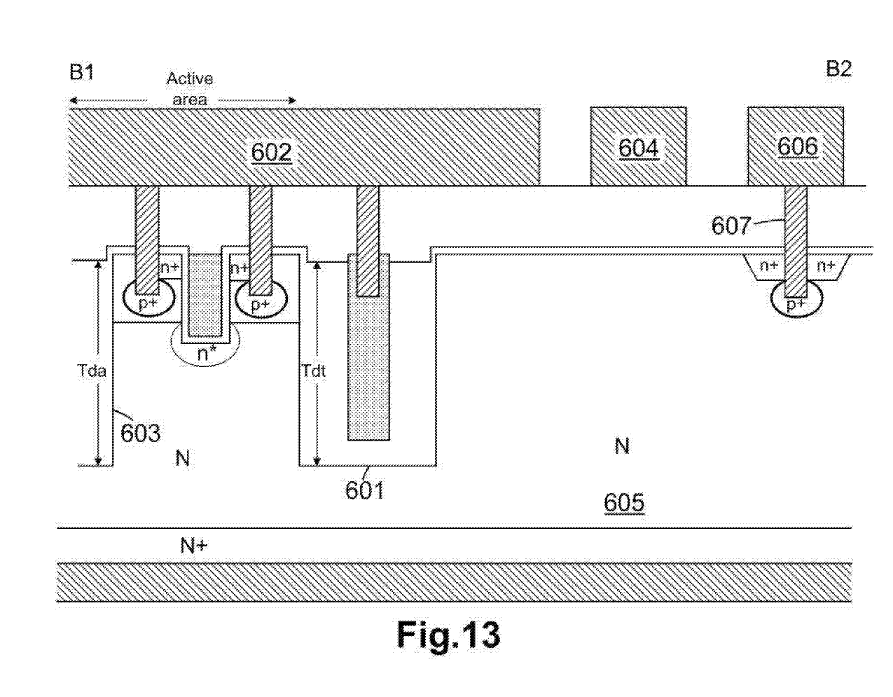

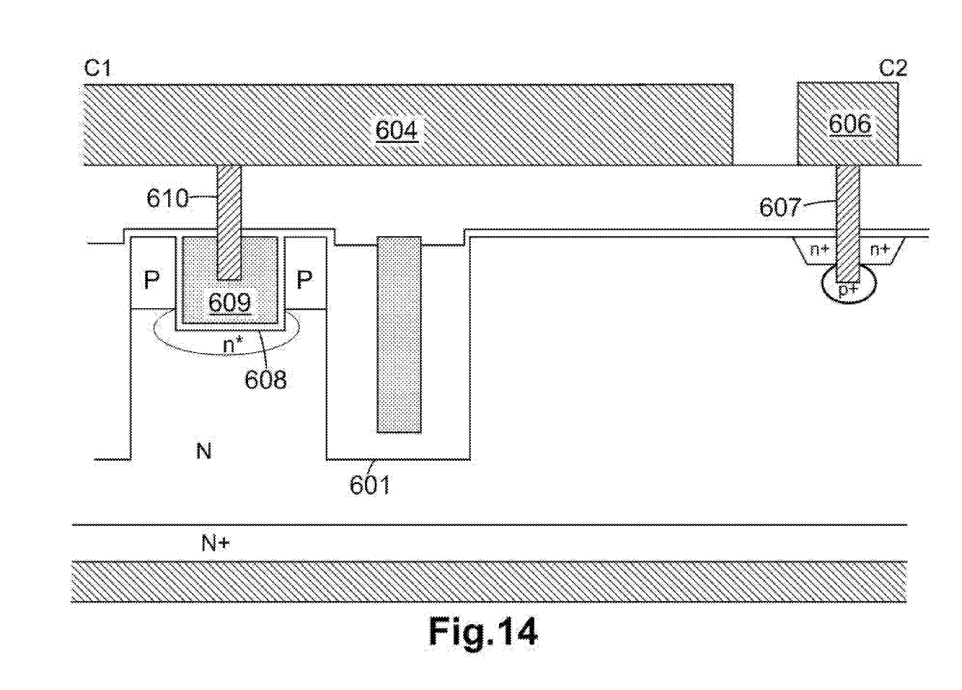

FIG. 12 shows another preferred top view according to the present invention with termination area which is similar to FIG. 10 except that, in FIG. 12, all the deep trenches in the active area have square and rectangular shape. To describe the detail structures, a preferred B1-B2 cross section is illustrated in FIG. 13 and a preferred C1-C2 cross section is illustrated in FIG. 14.

In FIG. 13, the deep trench termination ring 601 is formed under the source metal 802 and surrounding the active area, wherein trench depth Tdt of the deep trench termination ring 601 is the same as trench depth Tda of the deep trench 603 in the active area. The gate metal runner 604 is formed surrounding outer of the deep trench termination ring 601 above the N epitaxial layer 605; and the channel stop ring metal 606 is formed surrounding outer of the gate metal runner 604 above a channel stop ring 607.

FIG. 14 illustrates a wide gate trench 608 next to the deep trench termination ring 601, through said wide gate trench 608, the gate electrode 609 is being connected to the gate metal runner 604 by a trenched gate contact 610. In the C1-C2 cross section view, the channel stop ring metal 606 still surrounds outer of the gate metal runner 604 above the channel stop ring 607.

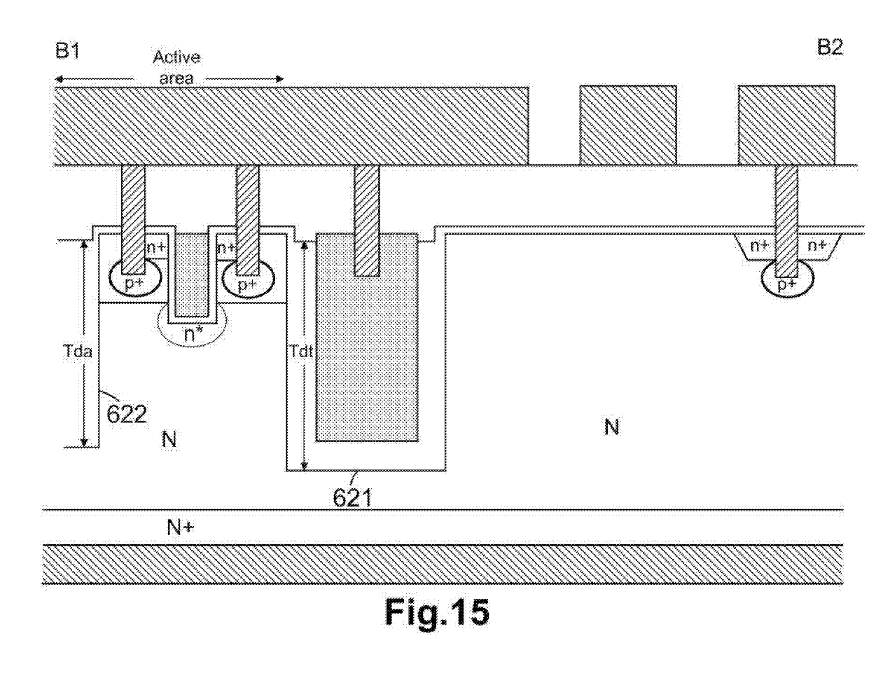

FIG. 15 shows another preferred B1-B2 cross section according to the present invention, which has a similar structure to FIG. 13 except that, in FIG. 15, the deep trench termination ring 621 has a greater trench depth and a greater trench width than the deep trench 622 in the active area, which means Tdt>Tda.

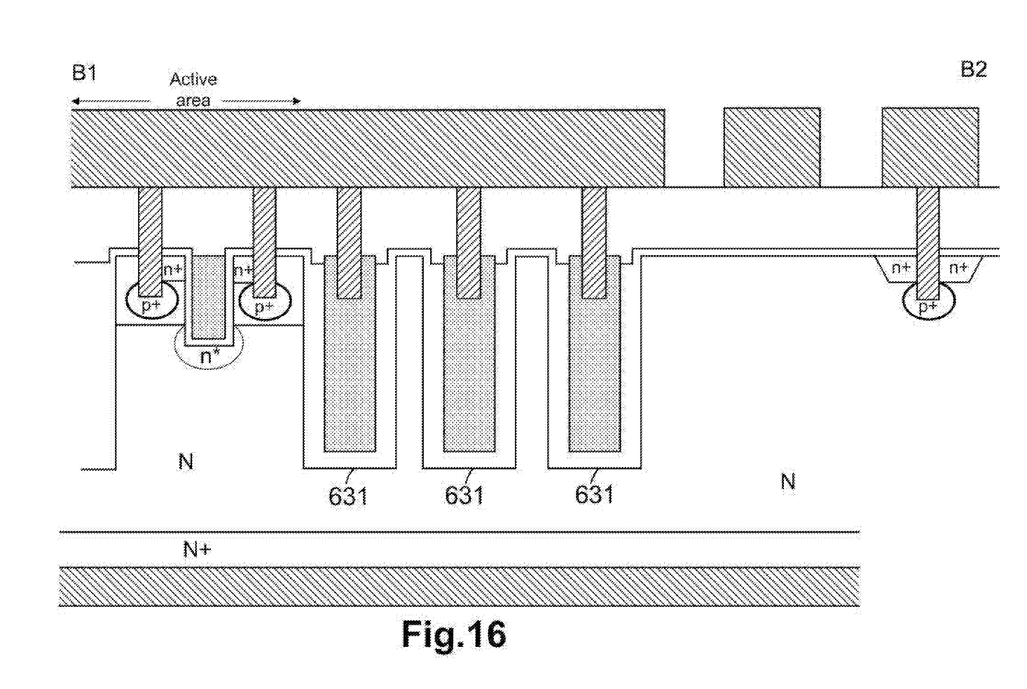

FIG. 16 shows another preferred B1-B2 cross sectional view according to the present invention, which has a similar structure to FIG. 13 except that, in FIG. 16, there are multiple deep trench termination rings 631 surrounding outer of the active area.

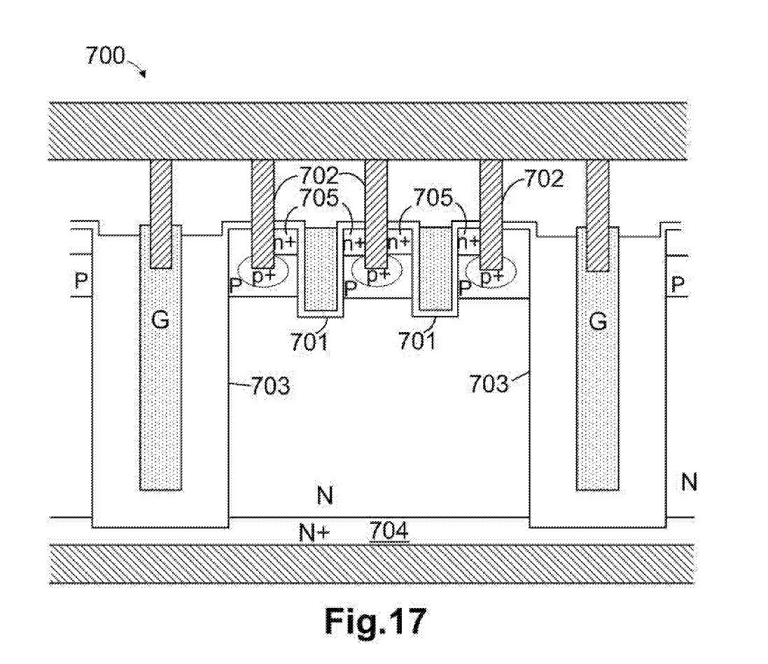

FIG. 17 is a cross-sectional view of another preferred embodiment according to the present invention for showing an N-channel trench MOSFET 700, in which there are multiple gate trenches 701 (there are 2 gate trenches in this embodiment) and multiple trenched source-body contacts 702 in the mesa between a pair of adjacent deep trenches 703 which have bottoms extending into said N+ substrate 704. What should be noticed is that, the n+ source region 705 locates between sidewall of each trenched source-body contact 702 and an adjacent gate trench 701, not locates between sidewall of each trenched source-body contact 702 and an adjacent deep trench 703.

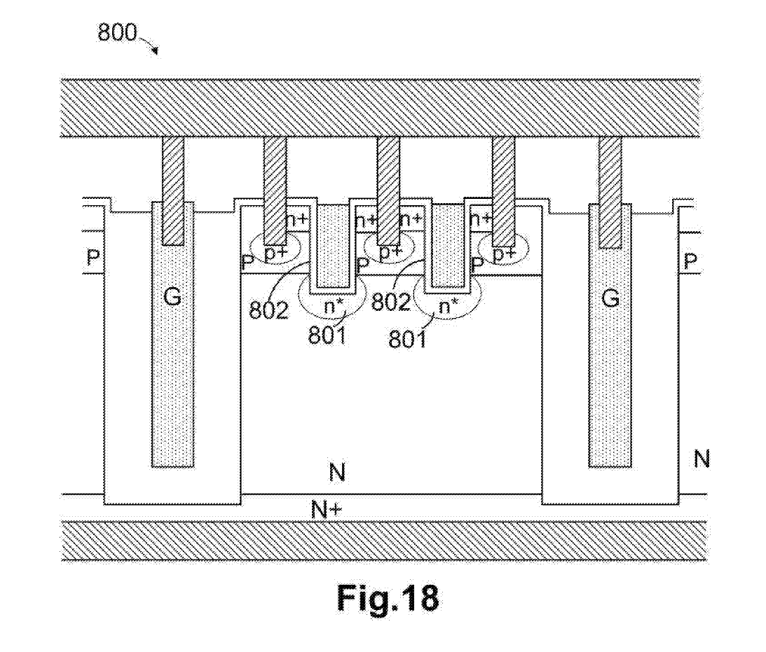

FIG. 18 is a cross-sectional view of another preferred embodiment according to the present invention for showing an N-channel trench MOSFET 800 which is similar to the trench MOSFET 700 in FIG. 17 except that, in FIG. 18, an additional n* trench bottom ion implantation area 801 is formed surrounding bottom of the gate trench 802, in order to reduce gate charge as well as Rds.

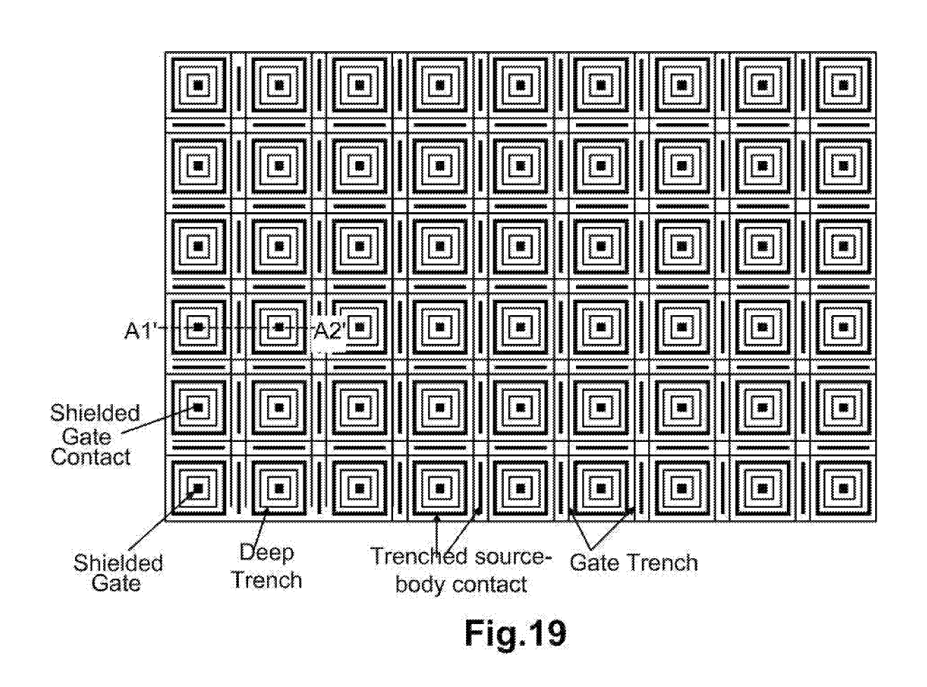

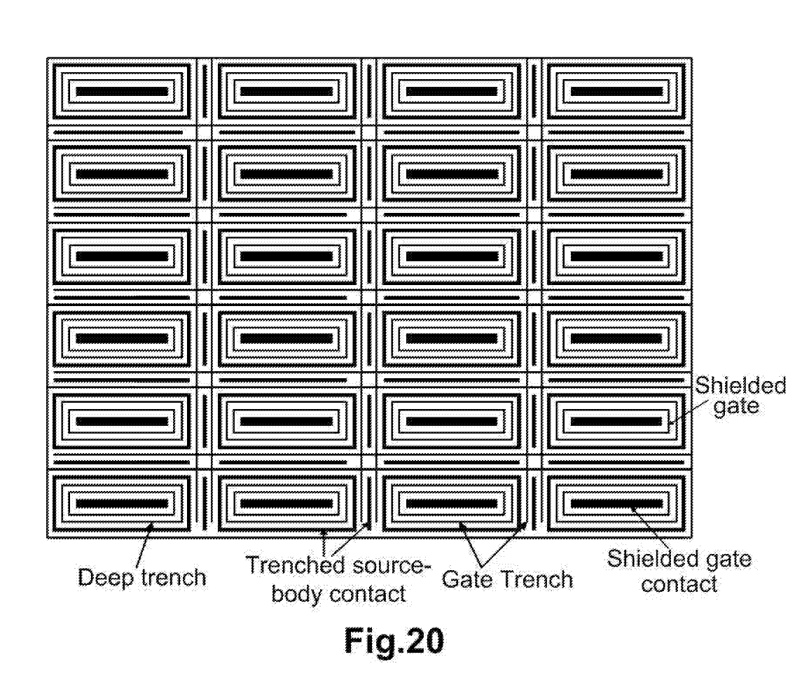

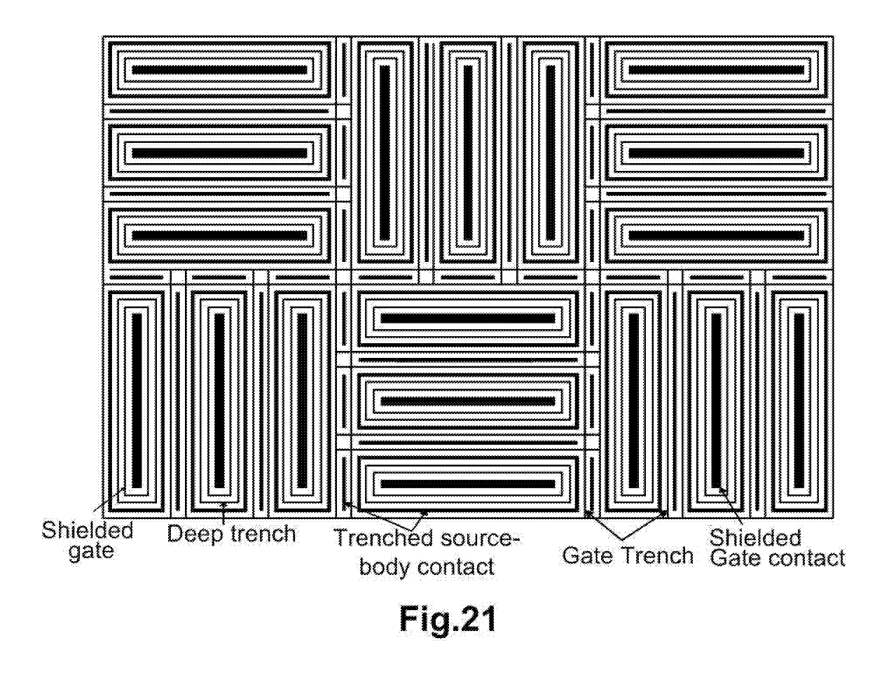

FIG. 19 shows a preferred top view according to the present invention with square closed cell layout. In which the preferred A1′-A2′ cross-sectional views could be represented by the embodiments shown in FIGS. 17-18. Between every two adjacent deep trenches, there are multiple gate trenches and multiple trenched source-body contacts (FIG. 19 shows there are 2 gate trenches and 3 trenched source-body contacts) in the mesa area between two adjacent deep trenches. FIGS. 20-21 show another preferred top views having multiple gate trenches between two adjacent deep trenches according to the present invention. FIG. 20 shows a preferred top view with rectangular closed cell layer, in which all said rectangular closed cells are arranged in single orientation. FIG. 21 shows a preferred top view with rectangular closed cell layout, in which all said rectangular closed cells are arranged in multiple orientations.

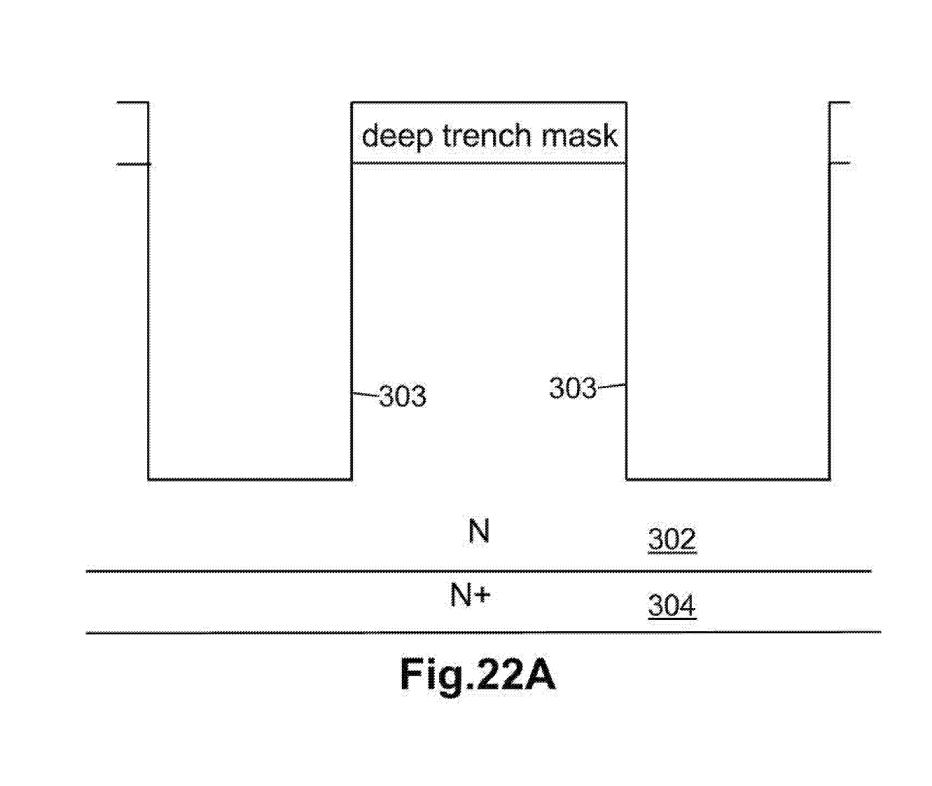

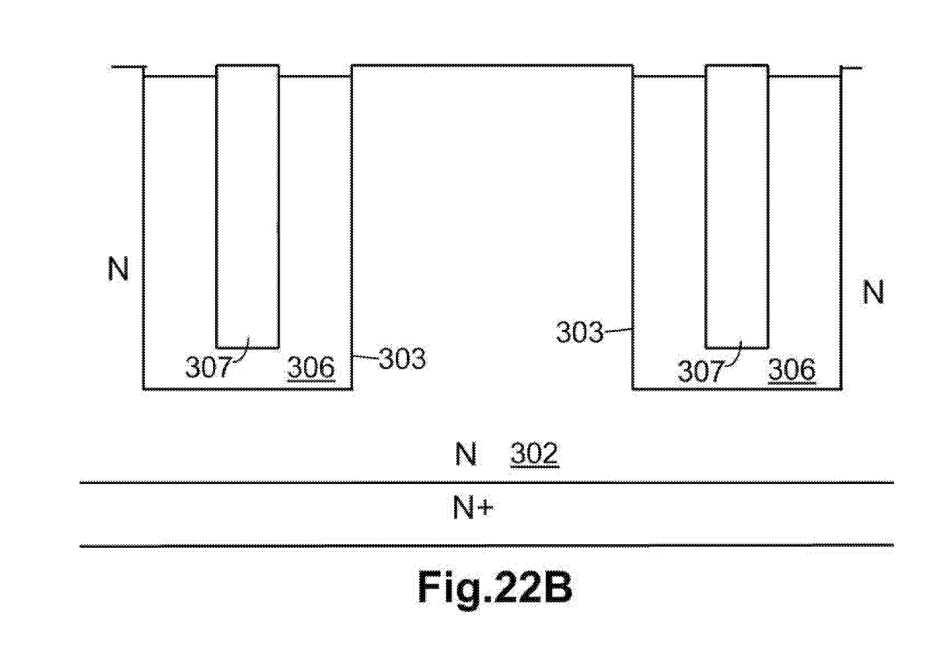

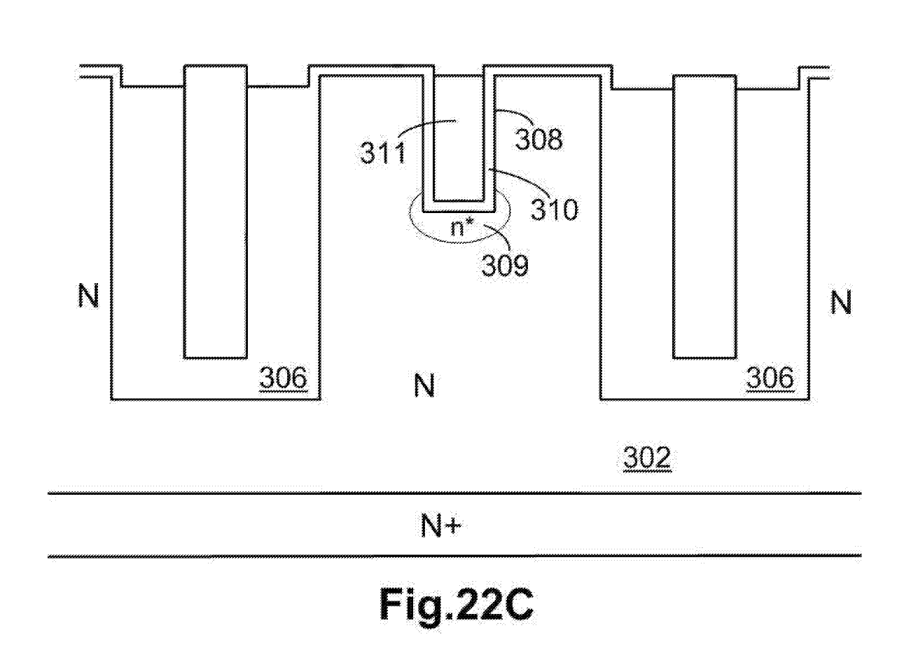

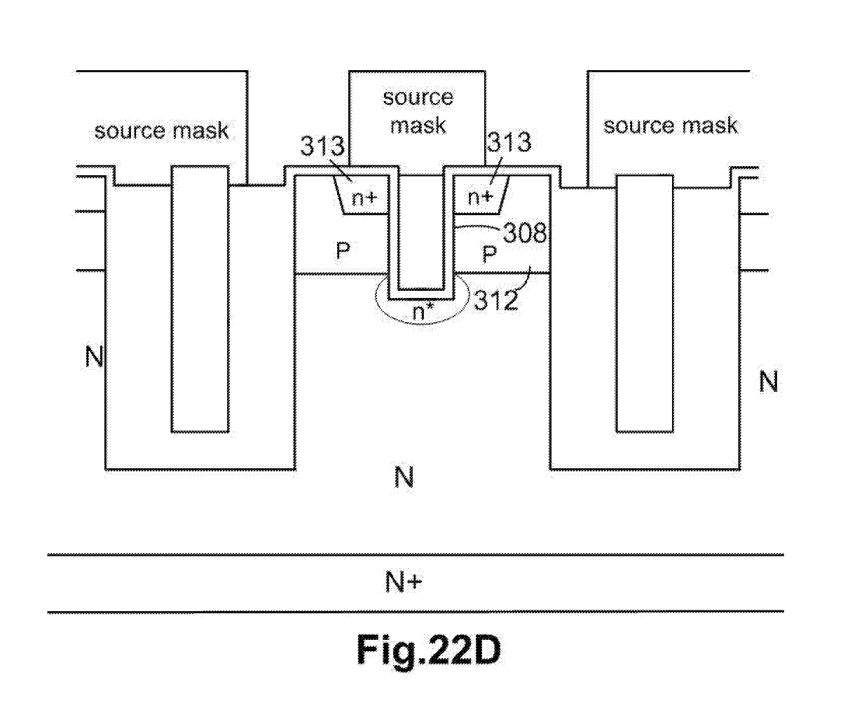

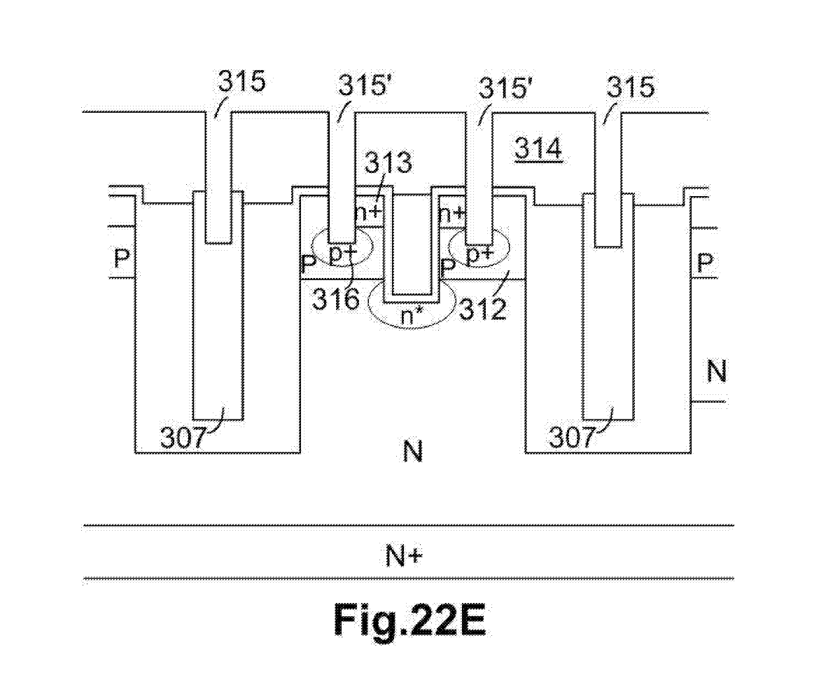

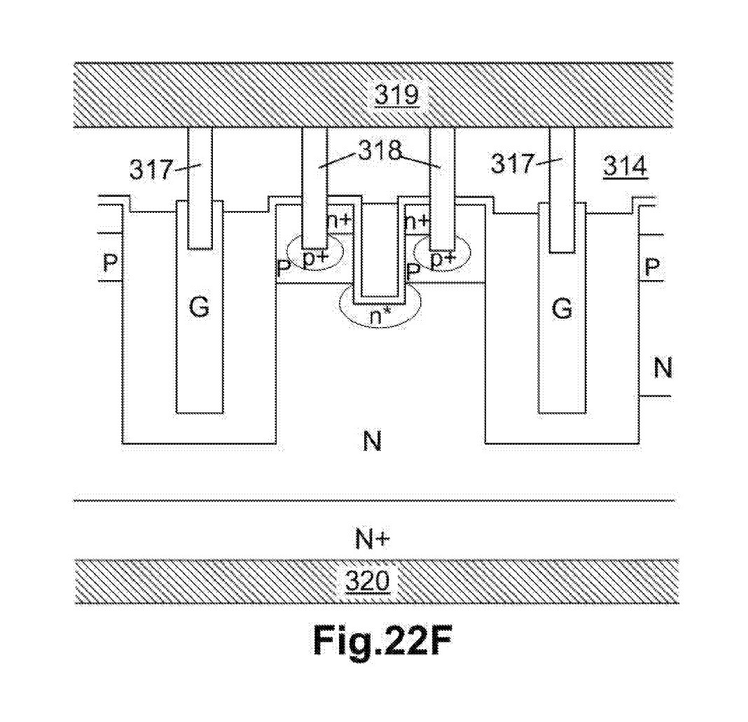

FIGS. 22A-22F are a serial of exemplary steps that are performed to form the invention trench MOSFET 300 of FIG. 3. In FIG. 22A, an N epitaxial layer 302 is grown on an N+ substrate 304. Next, a deep trench mask (e.g., oxide layer) is formed onto a top surface of said N-epitaxial layer 302 for definition of areas for deep trenches 303. Then, after dry oxide etch and dry silicon etch, a pair of deep trenches 303 are etched penetrating through open regions in the hard mask, and extending into said N-epitaxial layer 302.

In FIG. 22B, in order to form a dielectric material 306 inside said deep trenches 303, a step of thermal oxide grown and/or a step of thick oxide deposition can be chosen to used. Next, a first doped poly deposition and etch back are successively performed to form the shielded gate electrode 307 inside each of said deep trench 303. After that, a step of oxide etch back is carried out to remove unnecessary part of oxide above the top surface of said N epitaxial layer 302.

FIG. 22C, by applying a gate trench mask (not shown), a gate trench 308 is formed by dry silicon etch. Next, an ion implantation with N type dopant is carried out to form n* trench bottom ion implantation area 309. Then, an oxide layer is grown along inner surface of said gate trench 308 and top surface of said N epitaxial layer 302 to serve as gate oxide layer 310 which has a thinner thickness than said dielectric material 306. After that, a second doped poly deposition and etch back or CMP are successively performed to form the gate electrode 311.

In FIG. 22D, a body implantation of P type dopant is carried out over entire top surface and followed by a diffusion step to form a P body region 312 surrounding sidewalls of said gate trench 308. Then, by apply a source mask, a source implantation of N type dopant is carried out and followed by a diffusion step to form n+ source regions 313 above said P body region 312.

In FIG. 22E, another oxide layer is deposited onto top surface of the structure to serve as a contact insulation interlayer 314. Then, after applying a contact mask (not shown), a plurality of openings 315 and 315′ are formed by dry oxide etch and dry silicon etch, wherein said openings 315 are penetrating through said contact insulation interlayer 314 and extending into said shielded gate electrode 307, said openings 315′ are penetrating through said contact insulation interlayer 314, said n+ source region 313 and extending into said P body region 312. Then, a BF2 ion implantation and diffusion step is successively carried out to form a p+ ohmin-contact region 316 surrounding each bottom and said openings 315′ in said P body region 312.

In FIG. 22F, a barrier layer of Ti/TiN or Co/TiN or Ta/TiN is first deposited on sidewalls and bottoms of all said openings 315 and 315′ in FIG. 22E. Then, a tungsten material layer is deposited on said barrier layer, after which said tungsten material layer and said barrier layer are etched back to from: shielded gate contacts 317 and trenched source-body contacts 318. Then, a metal of Al alloys or Cu padded by a resistance-reduction layer Ti or Ti/TiN underneath is deposited onto said contact interlayer 314, and followed by a metal etching process by employing a metal mask (not shown) to be patterned as a front source metal 319. At last, a drain metal 320 is deposited on rear side of the N+ substrate 304.

Although the present invention has been described in terms of the presently preferred embodiments, it is to be understood that such disclosure is not to be interpreted as limiting. Various alternations and modifications will no doubt become apparent to those skilled in the art reading the above disclosure. Accordingly, it is intended that the appended claims be interpreted as covering all alternations and modifications as fall within the true spirit and scope of the invention.

What is claimed is:

1. A trench MOSFET having separated shielded gate, comprising:
at least one gate trench surrounding a deep trench as a closed cell shape, wherein said deep trench comprising a shielded gate formed inside; and
a trenched source-body contact disposed between one said gate trench and an adjacent deep trench;
a substrate of a first conductivity type;
an epitaxial layer of said first conductivity type onto said substrate, wherein said epitaxial layer has a lower doping concentration than said substrate;
said deep trench having a greater trench depth than said gate trench;
said shielded gate being formed within said deep trench and surrounded with a dielectric material;
a mesa area between a pair of adjacent deep trenches;
a body region of a second conductivity type extending in said mesa area;
a source region of said first conductivity type above said body region, locating between sidewall of each said gate trench and adjacent trenched source-body contact;
said gate trench filled with gate electrode padded by a gate oxide layer, starting from top surface of said epitaxial layer and down penetrating through said source region and extending into said epitaxial layer in said mesa area, wherein said gate oxide layer has a thickness thinner than said dielectric material ; and
a source metal connected with the shielded gate through a shielded gate contact and connected with the source region through the trenched source-body contact.

2. The trench MOSFET of claim 1 further comprising a trench bottom ion implantation region of said first conductivity type and surrounding at least bottom of each said gate trench under said body region.

3. The trench MOSFET of claim 1, wherein said deep trench is formed within said epitaxial layer, and has a trench bottom above a common interface between said epitaxial layer and said substrate.

4. The trench MOSFET of claim 1, wherein said deep trench is extending into said substrate, and has a trench bottom under a common interface between said epitaxial layer and said substrate.

5. The trench MOSFET of claim 1, wherein said epitaxial layer further comprising a first epitaxial layer under a second epitaxial layer, wherein said second epitaxial layer has a higher doping concentration than said first epitaxial layer, said deep trench is penetrating through said second epitaxial layer and extending into said first epitaxial layer, and has a trench bottom above a common interface between said first epitaxial layer and said substrate.

6. The trench MOSFET of claim 1, wherein there are multiple gate trenches in the mesa area between a pair of said deep trenches.

7. The trench MOSFET of claim 1 wherein said gate trench has a square shape.

8. The trench MOSFET of claim 1 wherein said gate trench has a rectangular shape and arranged in single orientation.

9. The trench MOSFET of claim 1 wherein said gate trench has a rectangular shape and arranged in multiple orientation.

10. The trench MOSFET of claim 1 wherein said gate trench has a circle shape.

11. The trench MOSFET of claim 1 wherein said gate trench has a hexagon shape.

12. The trench MOSFET of claim 1 wherein said trenched source-body contact each filled with a contact metal plug extending into said body region in said mesa.

13. The trench MOSFET of claim 1 further comprising a body contact region of said second conductivity type in said body region and surrounding at least bottom of each said trenched source-body contact, wherein said body contact region has a higher doping concentration than said body region.

14. The trench MOSFET of claim 13, wherein said contact metal plug is a tungsten plug padded by a barrier metal layer of Ti/TiN or Co/TiN or Ti/TiN.

15. The trench MOSFET of claim 1 further comprising a termination area which comprises at least a deep trench ring surrounding said active area, wherein each said deep trench ring is filled with said shielded gate and connected with said source metal.

16. The trench MOSFET of claim 15, wherein said deep trench ring has trench depth and trench width same as said deep trench in said active area.

17. The trench MOSFET of claim 15, wherein said deep trench ring has greater trench depth and greater trench width than said deep trench in said active area.

18. The trench MOSFET of claim 1 further comprising a gate metal runner extending from a gate metal pad, crossing over said termination area and connecting to said gate electrode.

19. The trench MOSFET of claim 15, wherein said deep trench ring surrounds not only the active area, but also portion of said gate metal pad.

20. A Method for manufacturing a trench MOSFET comprising the steps of:
growing an epitaxial layer of a first conductivity type upon a substrate of the first conductivity type, wherein the epitaxial layer having a lower doping concentration than the substrate;
forming a deep trench mask such as an oxide onto a top surface of said epitaxial layer for definition of a plurality of deep trenches;
forming said gate trenches, and a mesa between two adjacent deep trenches in said epitaxial layer by etching through open regions in the deep trench mask;
removing the hard mask;
forming a dielectric material along inner surfaces of said gate trenches by thermal oxide growth or oxide deposition;
depositing a first doped poly-silicon layer filling said deep trenches to serve as shielded gate;
etching back said first doped poly-silicon and the padded oxide layer from unnecessary portion;
etching a gate trench in said mesa between two adjacent deep trenches by applying a trench mask;
carrying out ion implantation of said first conductivity type to form trench bottom ion implantation area surrounding at least bottom of said gate trench;
forming a thin oxide layer to serve as a gate oxide layer covering a top surface of said epitaxial layer, along inner surface of said gate trench;
depositing a second doped poly-silicon layer filling said gate trench to serve as a gate electrode;
etching back said second doped poly-silicon layer by CMP (Chemical Mechanical Polishing) or plasma etch;
carrying out a body implantation of the second conductivity type dopant and a step of body diffusion to form body regions;
applying a source mask onto the top surface of the epitaxial layer, and carrying out a source implantation of said first conductivity type dopant and a source diffusion to form source regions;
forming a contact insulating interlayer covering top surface of said epitaxial layer; and
etching openings and filling contact metal plug in those openings to form shielded gate contacts and trenched source-body contacts.

21. The method of claim 20, after forming said source regions, further comprising:
carrying out BF2 ion implantation to form a body contact regions of said second conductivity type in said body region and surrounding at least bottom of each said trenched source-body contacts, said body contact region having a heavier doping concentration than said body region.

22. The method of claim 21, after forming said body contact doped regions, further comprising:
depositing a tungsten metal layer padded by a barrier metal layer in said trenched source-body contacts and said shielded gate contacts.
